(19) United States
(12) Patent Application Publication
(10) Pub. No.: US 2009/0075597 A1
(43) Pub. Date: Mar. 19, 2009

(54) DEVICE, SYSTEM, AND METHOD OF LOW-NOISE AMPLIFIER

(76) Inventors: Ofir Degani, Haifa (IL); Yair Shemesh, Haifa (IL)

Correspondence Address: EMPK & SHILOH ,LLP, C/O INTELLEVATE , LLC, P.O BOX 52050, MINNEAPOLIS, MN, 55402, US

(21) Appl. No.: 11/856,739

(22) Filed: Sep. 18, 2007

(51) Int. Cl. H03F 3/00

(52) U.S. Cl. 455/63.1; 330/116

(57) ABSTRACT

Device, system, and method of low-noise amplifier. For example, an apparatus includes a low-noise amplifier to convert a single-ended wireless communication signal into a corresponding differential signal.

### BACKGROUND

A wireless communication device may include a receiver chain having, for example, an antenna, one or more Radio Frequency (RF) filters, a Low-Noise Amplifier (LNA), a mixer associated with a Local Oscillator (LO), and other components. The antenna may receive a single-ended RF signal, whereas some components of the RF Integrated Circuit (RFIC) of the wireless communication device may require a differential signal for processing. For example, a differential topology may be used for on-chip integrated mixed-signal circuits, in order to improve the circuit immunity to on-chip spurious signals (e.g., from the LO, from a clock, or other components). Accordingly, the wireless communication device may require a single-ended to differential converter, namely, an unbalanced signal to balanced signal converter.

In some wireless communication devices, the receiver chain includes a Balance/Unbalance (BALUN) component, positioned in front of the on-chip differential LNA. The BALUN may include an off-chip transformer or bridge-type lumped element, or an on-chip passive transformer. Unfortunately, such BALUN components may be inefficient in terms of cost and/or area consumption. Additionally, a BALUN positioned in front of the LNA may contribute to signal loss, and may result in degradation of the Noise Figure (NF)

In other wireless communication devices, the receiver chain may include an on-chip single-ended LNA followed by a BALUN component. The BALUN may include, for example, a passive transformer, or an active transistor core utilizing a feedback loop. Unfortunately, such topology may expose the input of the single-ended LNA to spurious signals. Additionally, the BALUN component may be inefficient in terms of cost, area consumption and/or power consumption. Furthermore, a BALUN implemented using an integrated transformer may contribute to signal loss, may result in degradation of the NF, may reduce the effective gain of the combination of the LNA and the BALUN, and may further increase the impact of noise contribution from subsequent stages on the overall NF.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of a wireless communication system in accordance with a demonstrative embodiment of the invention; and

FIG. 2 is a schematic illustration of multiple charts representing multiple performance aspects of a receiver (or of components thereof) in accordance with a demonstrative embodiment of the invention.

### DETAILED DESCRIPTION

In the following detailed description, numerous specific details are set forth in order to provide a thorough understanding of some embodiments of the invention. However, it will be understood by persons of ordinary skill in the art that embodiments of the invention may be practiced without these specific details. In other instances, well-known methods, procedures, components, units and/or circuits have not been described in detail so as not to obscure the discussion.

Discussions herein utilizing terms such as, for example, “processing,” “computing,” “calculating,” “determining,” “establishing”, “analyzing”, “checking”, or the like, may refer to operation(s) and/or process(es) of a computer, a computing platform, a computing system, or, other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality” as used herein includes, for example, “multiple” or “two or more”. For example, “a plurality of items” includes two or more items.

Although portions of the discussion herein relate, for demonstrative purposes, to wired links and/or wired communications, embodiments of the invention are not limited in this regard, and may include one or more wired or wireless links, may utilize one or more components of wireless communication, may utilize one or more methods or protocols of wireless communication, or the like. Some embodiments of the invention may utilize wired communication and/or wireless communication.

Some embodiments of the invention may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a non-mobile or non-portable device, a wireless communication station, a wireless communication device, a wireless Access Point (AP), a wired or wireless router, a wired or wireless modem, a wired or wireless network, a Local Area Network (LAN), a Wireless LAN (WLAN), a Metropolitan Area Network (MAN), a Wireless MAN (WMAN), a Wide Area Network (WAN), a Wireless WAN (WWAN), a Personal Area Network (PAN), a Wireless PAN (WPAN), devices and/or networks operating in accordance with existing IEEE 802.11, 802.11a, 802.11b, 802.11g, 802.11n, 802.16, 802.16d, 802.16e, 802.20 standards and/or future versions and/or derivatives and/or Long Term Evolution (LTE) of the above standards, units and/or devices which are part of the above networks, one way and/or two-way radio communication systems, cellular, radio-telephone communication systems, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, a wired or wireless handheld device (e.g. BlackBerry, Palm Treo), a Wireless Application Protocol (WAP) device, or the like.

Some embodiments of the invention may be used in conjunction with one or more types of wireless communication signals and/or systems, for example, Radio Frequency (RF), Infra Red (IR), Frequency-Division Multiplexing (FDM). Orthogonal FDM (OFDM), Time-Division Multiplexing (TDM), Time-Division Multiple Access (TDMA), Extended TDMA (E-TDMA), General Packet Radio Service (GPRS), extended GPRS, Code-Division Multiple Access (CDMA), Wideband CDMA (WCDMA), CDMA 2000, Multi-Carrier Modulation (MDM), Discrete Multi-Tone (DMT), Bluetooth®, Global Positioning System (GPS), Wi-Fi, Wi-Max, ZigBee™, Ultra-Wideband (UWB), Global System for Mobile communication (GSM), 2G, 2.5G, 3G, 3.5G, or the like. Embodiments of the invention may be used in various other devices, systems and/or networks.

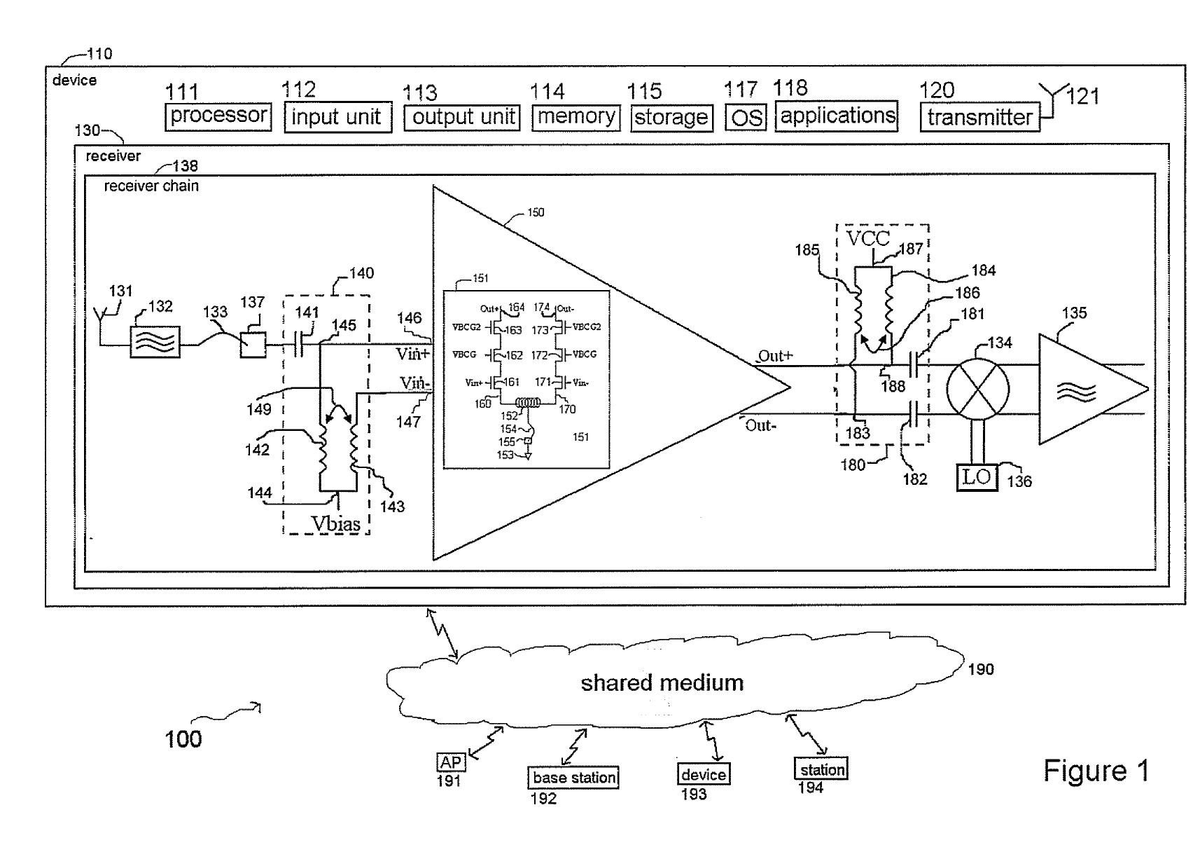

FIG. 1 schematically illustrates a block diagram of a wireless communication system 100 in accordance with some demonstrative embodiments of the invention. System 100 may include, for example, a wireless communication device 110 able to communicate using a shared medium 190 with one or more other devices, e.g., a wireless Access Point (AP) 191, a wireless base station 192, a wireless communication device 193, a wireless communication station 194, or the like.

Device 110 may be or may include, for example, a mobile phone, a cellular phone, a handheld device, a computing device, a computer, a Personal Computer (PC), a server computer, a client/server system, a mobile computer, a portable computer, a laptop computer, a notebook computer, a tablet computer, a network of multiple inter-connected devices, or the like.

Device 110 may include, for example, a processor 111, an input unit 112, an Output unit 113, a memory unit 114, a storage unit 115, a transmitter 120, and a receiver 130. Device 100 may optionally include other suitable hardware components and/or software components.

Processor 111 includes, for example, a Central Processing Unit (CPU), a Digital Signal Processor (DSP), one or more processor cores, a single-core processor, a dual-core processor, a multiple-core processor, a microprocessor, a host processor, a controller, a plurality of processors or controllers, a chip, a microchip, one or more circuits, circuitry, a logic unit, an Integrated Circuit (IC), an Application-Specific IC (ASIC), of any other suitable multi-purpose or specific processor or controller. Processor 111 executes instructions, for example, of an Operating System (OS) 117 of device 100 or of one or more applications 118.

Input unit 112 includes, for example, a keyboard, a keypad, a mouse, a touch-pad, a track-ball, a stylus, a microphone, or other suitable pointing device or; input device. Output unit 113 includes, for example, a monitor, a screen, a Cathode Ray Tube (CRT) display unit, a Liquid Crystal Display (LCD) display unit, a plasma display unit, one or more audio speakers, or other suitable output devices.

Memory unit 114 includes, for example, a Random Access Memory (RAM), a Read Only Memory (ROM), a Dynamic RAM (DRAM), a Synchronous DRAM (SD-RAM), a flash memory, a volatile memory, a non-volatile memory, a cache memory, a buffer a short term memory unit, a long term memory unit, or other suitable memory units. Storage unit 115 includes, for example, a hard disk drive, a floppy disk drive, a Compact Disk (CD) drive, a CDROM drive, a Digital Versatile Disk (DVD) drive, or other suitable removable or non-removable storage units. Memory unit 114 and/or storage unit 115, for example, store data processed by device 110.

Transmitter 120 may include, for example, a wireless Radio Frequency (RF) transmitter able to transmit wireless RF signals, blocks, frames, transmission streams, packets, messages and/or data, e.g., through an antenna 121.

Receiver 130 may include, for example, a wireless Radio Frequency (RF) receiver able to receive wireless RF signals, blocks, frames, transmission streams, packets, messages and/or data, e.g., through an antenna 131.

Optionally, transmitter 120 and receiver 130 may be implemented using a transceiver, a transmitter-receiver, or other suitable component. Optionally, antenna 121 and antenna 131 may be implemented using a common antenna, a common set of multiple antennas, or other suitable component. For example, antenna 121 and/or antenna 131 may include an internal and/or external RF antenna, a dipole antenna, a monopole antenna, an omni-directional antenna, an end fed antenna, a circularly polarized antenna, a micro-strip antenna, a diversity antenna, or other type of antenna suitable for transmitting and/or receiving wireless communication signals, blocks, frames, transmission streams, packets, messages and/or data.

In some embodiments, some or all of the components of device 110 may be enclosed in a common housing, packaging, or the like, and may be interconnected or operably associated using one or more wired or wireless links. In other embodiments, components of device 110 may be distributed among multiple or separate devices or locations.

Receiver 130 may include a receiver chain 138 having the antenna 131 and a filter 132, further connected through a bond-wire 133 and a pad 137 to an input matching network 140, a LNA 150 having a transistor core 151, an output matching network 180, a mixer 134 associated with a Local Oscillator (LO) 136, and an amplifier/filter 135. An incoming, single-ended, wireless communication signal is received by the antenna 131, filtered by the filter 132, and enters the input matching network 140.

The input matching network 140 includes a series capacitor 141, and a differential shunt inductor 149 having two mutually coupled inductors 142 and 143) connected in parallel to each other. A biasing voltage (“Vbias”) is injected at a node 144 between the two inductors 142 and 143, in order to provide Direct Current (DC) bias to the common source stage. At a node 146, the LNA 150 receives a positive input voltage; and at a node 147, the LNA 150 receives a negative input voltage, A first side of the differential shunt inductor 149 is connected at a node 145, between the capacitor 141 and the node 146, A second side of the differential shunt inductor 149 is connected to the node 147. The differential shunt inductor 149 of the input matching network 140 operates as auto-transformer, coupling the input signal to both inputs of the LNA 150 (namely, to nodes 146 and 147), and more particularly, coupling the input signal to the inputs of the LNA transistor core 151. The signal received by the LNA 150 is single-elided; the differential shunt inductor 149 may not be a perfect transformer, and thus the two inputs of the LNA 150 may not be perfectly balanced.

The LNA 150 includes transistor core 151, which further rejects the common mode signal received at the input nodes 146 and 147. The transistor core 151 is symmetric and differential, and includes a first path 160 connected in parallel with a second path 170. A degeneration inductor 152 is connected between the first path 160 and the second path 170, and is further connected to a ground 153 (e.g., through a bond-wire 154 and a pad 155).

The first path 160 includes a first transistor 161, and a gate terminal of the first transistor 161 receives the positive input voltage from node 146. The first path 160 further includes a second transistor 162, which receives a first common gate biasing voltage through its gate terminal; and a third transistor 163, which receives a second common gate biasing voltage through its gate terminal. A node 164 of the first path 160 outputs the positive output current of the transistor core 151.

The second path 170 includes a first transistor 171, and a gate terminal of the first transistor 171 receives the negative input voltage from node 147. The second path 170 further includes a second transistor 172, which receives the first common gate biasing voltage through its gate terminal; and a third transistor 173, which receives the second common gate biasing voltage through its gate terminal A node 174 of the second path 170 outputs the negative output current of the transistor core 151.

The output matching network 180 receives the positive output voltage of the transistor core 151 at a first network path that includes a first capacitor 181; and further receives the negative output voltage of the transistor core 151 at a second network path that includes a second capacitor 182. The output matching network 180 further includes a differential shunt inductor 186 having two mutually coupled inductors 184 and 185 connected in parallel to each other. A power supply voltage (“Vcc”) is received at a node 187 between the two inductors 184 and 185.

A first side of the differential shunt inductor 186 is connected at a node 185, between the capacitor 182 and the incoming negative side current. A second side of the differential shunt inductor 186 is connected to a node 188, between capacitor 181 and the incoming positive side currents. The differential shunt inductor 186 of the output matching network 180 operates as auto-transformer and further improves the output balance.

The differential output of the output matching network 180 enters the mixer 134. Optionally, the mixer 134 may have high impedance, and this may further improve the balance of the differential signal.

In some embodiments, receiver chain 138 includes a highly-integrated single-stage RF LNA 150 with embedded un-balanced to balanced conversion, and without using passive and/or active BALUN components (or compensation circuits) before and/or after the LNA 150. Optionally, using sub-micron Complementary Metal-Oxide Semiconductor (CMOS) technology, a high NF LNA 150 may be achieved (e.g., sub-2 dB), thereby allowing integration and miniaturization of substantially all the receiver 130 within a CMOS chip. The receiver chain 138 may thus be area-efficient and power-efficient, using the single-stage LNA 150 with embedded single-ended to differential (namely, unbalanced to balanced) conversion.

In some embodiments, receiver chain 138 may be implemented using triple cascode topology, regular cascode topology, common source differential pair topology, cross couple pair topology, or other suitable topologies.

In some embodiments, transistor core 151 may have a substantially fixed or constant gain, a variable gain, gain stepping (e.g., using current steering, or switched resistors bank), or other suitable types of gain control.

In some embodiments, receiver 130 may be implemented using a single-ended input receiver 130 on the RFIC, without a BALUN component, and without a Front-End Module LNA, such that the RFIC integrates a LNA and a single-ended to differential (namely, unbalanced to balanced) conversion. In some embodiments, single-ended inductors and single-ended transistor core 151 may be used; in other embodiments, a single-ended input may be used in combination with differential inductors and differential transistor core 151; in some embodiments, a transformer may be used, before or after the LNA 150. Other suitable components may be used.

In some embodiments, at least part of the unbalanced to balanced conversion is achieved by the input matching network 140 before the LNA 150, thereby improving the immunity to spurious signals. The integration of single-ended to differential conversion with the LNA 150 (using the transistor core 151, the input matching network 140 and the output matching network 180, optionally implemented in one cell) allows implementation which may be power-efficient, area-efficient, cost-efficient, and/or having an improved NF (e.g., compared to a combination of a single-ended LNA and an active BALUN) In some embodiments, receiver 130 may be cost-efficient, for example, due to removal of the LNA and BALUN from the Front-End Module (FEM). Embodiments of the invention may provide other and/or additional benefits and/or advantages.

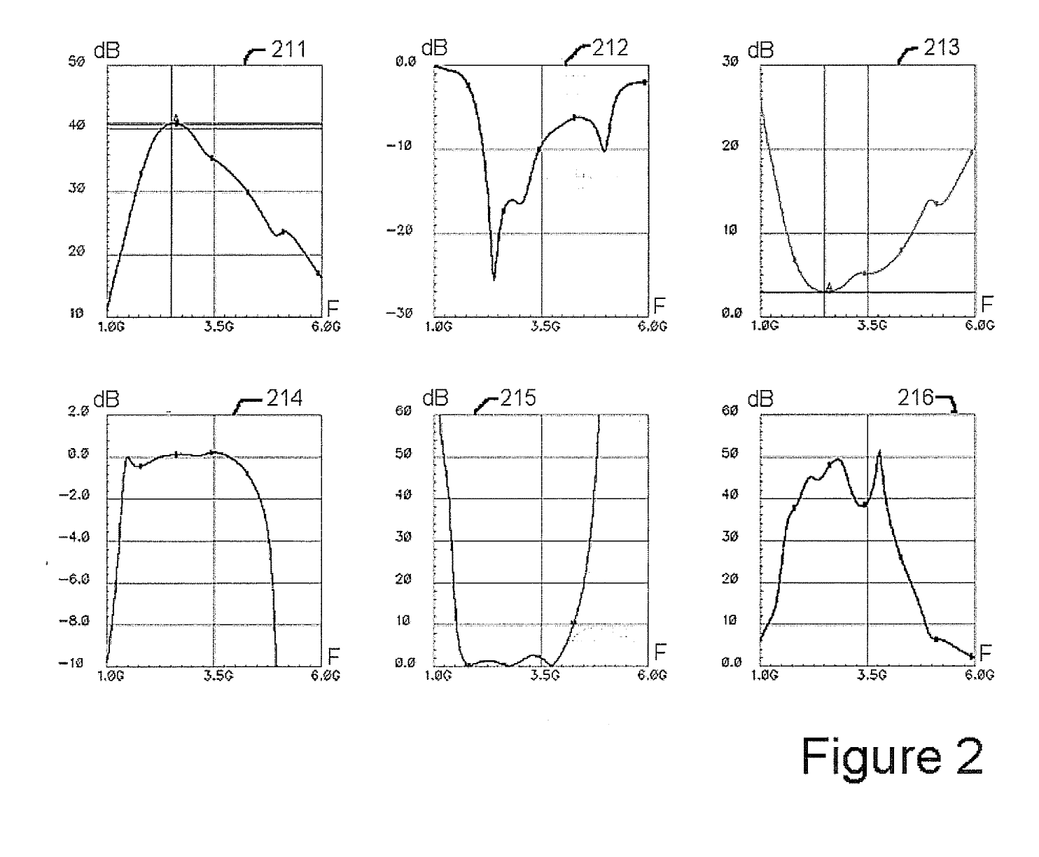

FIG. 2 schematically illustrates multiple charts 211-216 representing multiple performance aspects of a receiver (or of components thereof, e.g., a LNA or a receiver chain) in accordance with some demonstrative embodiments of the invention, e.g., based on results from a demonstrative simulation. Charts 211-216 are presented for demonstrative purposes, and embodiments of the invention (or other simulations thereof) may result in other charts.

In each of charts 211-216, the horizontal axis indicates frequency (e.g., in GHz); the simulation focused on a frequency of 2.5 GHz and on close frequencies. In each of charts 211-216, units on the vertical axis are indicated in dB.

Chart 211 demonstrates total gain of the receiver as a function of frequency in accordance with some embodiments of the invention. As demonstrated in chart 211, the total gain of the receiver is approximately 40 dB at a frequency of 2.5 GHz and at close frequencies.

Chart 212 demonstrates input matching (“S11”) of the LNA as a function of frequency in accordance with some embodiments of the invention. As demonstrated in chart 212, the input matching of the LNA is smaller than −10 dB at a frequency of 2.5 GHz and at close frequencies.

Chart 213 demonstrates Noise Figure (NF) of the receiver as a function of frequency in accordance with some embodiments of the invention. As demonstrated in chart 213, the NF of the whole receiver is approximately 3 dB at a frequency of 2.5 GHz and at close frequencies.

Chart 214 demonstrates gain balance of the LNA as a function of frequency in accordance with some embodiments of the invention. As demonstrated in chart 214, the gain balance of the LNA is approximately zero at a frequency of 2.5 GHz and at close frequencies. The gain balance may be calculated, for example, using the following equation, denoted Equation 1:

$$Gain\_balance ≡ 20 \times log 10 ( \frac{{V}_{OUT}^{+}}{{V}_{OUT}^{-}} ) \qquad Equation 1$$

Chart 215 demonstrates a phase balance of the LNA as a function of frequency in accordance with some embodiments of the invention. As demonstrated in chart 215, the phase balance of the LNA is approximately zero at a frequency of 2.5 GHz and at close frequencies. The phase balance may be calculated, for example, using the following equation, denoted Equation 2:

Phase_balance≡Phase(V_{OUT}⁺)−Phase(V_{OUT}⁻)−180| Equation 2

Chart 216 demonstrates an output Common Mode Rejection Ratio (CMRR) of the LNA as a function of frequency in accordance with some embodiments of the invention. As demonstrated in chart 216, the CMRR of the LNA is above 30 dB at a frequency of 2.5 GHz and at close frequencies. The CMRR may be calculated, for example, using the following equation, denoted Equation 3:

$$CMRR ≡ 20 \times log 10 ( \frac{{V}_{OUT}^{+} - {V}_{OUT}^{-}}{( {V}_{OUT}^{+} + {V}_{OUT}^{-} ) / 2} ) \qquad Equation 3$$

In some embodiments, a method may include, for example, receiving by a LNA a single-ended signal, and generating by the LNA a differential signal.

In some embodiments, the method may include, for example, in a transistor core of the LNA, receiving a positive input voltage and a negative input voltage, passing the positive input voltage through one or more transistors of a first path, and passing the negative input voltage through one or more transistors of a second, parallel, path; wherein a degeneration inductor is connected between the first path and the second path, the degeneration inductor further connected to a ground.

In some embodiments, the method may include, for example, passing the signal through an input matching network comprising one or more capacitors and a differential shunt inductor having first and second inductors, wherein a node between the first and second inductors is connected to a biasing voltage.

In some embodiments, the method may include, for example, passing the signal through an output matching network comprising one or more capacitors and a differential shunt inductor having first and second inductors, wherein a node between the first and second inductors is connected to a voltage of a power supply.

In some embodiments, the method may include, for example, passing the differential signal to a high-impedance differential mixer.

Other suitable operations may be used, and other suitable orders of operation may be used.

Some embodiments of the invention, for example, may take the form of an entirely hardware embodiment, an entirely software embodiment, or an embodiment including both hardware and software elements. Some embodiments may be implemented in software, which includes but is not limited to firmware, resident software, microcode, of the like.

Furthermore, some embodiments of the invention may take the form of a computer program product accessible from a computer-usable or computer-readable medium providing program code for use by or in connection with a computer or any instruction execution system. For example, a computer-usable or computer-readable medium may be or may include any apparatus that can contain, store, communicate, propagate, or transport the program for use by or in connection with the instruction execution system, apparatus, or device.

In some embodiments, the medium may be an electronic, magnetic, optical, electromagnetic, infrared, or semiconductor system (or apparatus or device) or a propagation medium. Some demonstrative examples of a computer-readable medium may include a semiconductor or solid state memory, magnetic tape, a removable computer diskette, a random access memory (RAM), a read-only memory (ROM), a rigid magnetic disk, and an optical disk. Some demonstrative examples of optical disks include compact disk-read only memory (CDROM), compact disk-read/write (CD-R/W), and DVD.

In some embodiments, a data processing system suitable for storing and/or executing program code may include at least one processor coupled directly or indirectly to memory elements, for example, through a system bus. The memory elements may include, for example, local memory employed during actual execution of the program code, bulk storage, and cache memories which may provide temporary storage of at least some program code in order to reduce the number of times code must be retrieved from bulk storage during execution.

In some embodiments, input/output or I/O devices (including but not limited to keyboards, displays, pointing devices, etc.) may be Coupled to the system either directly or through intervening I/O controllers. In some embodiments, network adapters may be coupled to the system to enable the data processing system to become coupled to other data processing systems or remote printers or storage devices, for example, through intervening private or public networks. In some embodiments, modems, cable modems and Ethernet cards are demonstrative examples of types of network adapters. Other suitable components may be used.

Functions, operations, components and/or features described herein with reference to one or more embodiments, may be combined with, or may be utilized in combination with, one or more other functions, operations, components and/or features described herein with reference to one or more other embodiments, or vice versa.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

What is claimed is:

1. An apparatus comprising:
a low-noise amplifier to convert a single-ended wireless communication signal into a corresponding differential signal,
wherein the low-noise amplifier comprises a transistor core embedded therein to receive a positive input voltage and a negative input voltage, to pass the positive input voltage through one or more transistors of a first path, and to pass the negative input voltage through one or more transistors of a second, parallel, path,
and wherein the transistor cote comprises a degeneration inductor connected between the first path and the second path, the degeneration inductor further connected to a ground.

2. The apparatus of claim 1, comprising:
an input matching network comprising one or more capacitors and a differential shunt inductor having first and second mutually coupled inductors.

3. The apparatus of claim 2, wherein a node between the first and second inductors of the input matching network is connected to a biasing voltage.

4. The apparatus of claim 1, comprising:
an output matching network comprising one or more capacitors and a differential shunt inductor having first and second mutually coupled inductors.

5. The apparatus of claim 4, wherein a node between the first and second inductors of the output matching network is connected to a voltage of a power supply.

6. The apparatus of claim 1, comprising:
a high-impedance differential mixer to receive the differential signal.

7. The apparatus of claim 1, wherein the apparatus comprises a receiver chain.

8. The apparatus of claim 1, wherein the apparatus comprises a wireless receiver.

9. The apparatus of claim 1, wherein the apparatus comprises a wireless communication device.

10. A wireless communication system comprising:
a wireless communication device comprising:
an input matching network comprising one or more capacitors and a first differential shunt inductor having first and second mutually coupled inductors;
a low-noise amplifier having an integrated transistor core to convert a single-ended wireless communication signal into a corresponding differential signal; and
an output matching network comprising one or more capacitors and a second differential shunt inductor having third and fourth mutually coupled inductors.

11. The wireless communication system of claim 10, wherein a node between the first and second inductors of the input matching network is connected to a biasing voltage.

12. The wireless communication system of claim 10, wherein a node between the third and fourth inductors of the output matching network is connected to a voltage of a power supply.

13. The wireless communication system of claim 10, comprising:
another wireless communication device to transmit wireless communication signals to said wireless communication device.

14. The wireless communication system of claim 10, wherein the integrated transistor core is to receive a positive input voltage and a negative input voltage, to pass the positive input voltage through one or more transistors of a first path, and to pass the negative input voltage through one or more transistors of a second, parallel, path.

15. The wireless communication system of claim 14, wherein the integrated transistor core comprises a degeneration inductor connected between the first path and the second path, the degeneration inductor further connected to a ground.
